(19) United States
(12) Patent Application Publication
(10) Pub. No.: US 2003/0116087 A1
(43) Pub. Date: Jun. 26, 2003

(54) Chamber hardware design for titanium nitride atomic layer deposition

(76) Inventors: Anh N. Nguyen, Milpitas, CA (US); Steve H. Chiao, San Jose, CA (US); Xiaoxiong Yuan, Cupertino, CA (US); Lawrence Chung-Lai Lei, Milpitas, CA (US); Ming Xi, Palo Alto, CA (US); Michael X. Yang, Palo Alto, CA (US); Sean M. Seutter, San Jose, CA (US); Toshio Itoh, Palo Alto, CA (US)

Correspondence Address: Patent Counsel, Applied Materials, Inc., P.O. Box 450-A, Santa Clara, CA, 95052, US

(21) Appl. No.: 10/032,293

(22) Filed: Dec. 21, 2001

(51) Int. Cl. C23F 1/00; C23C 16/00; H01L 21/306

(52) U.S. Cl. 118/715; 156/345.34; 438/791

(57) ABSTRACT

A lid assembly and a method for ALD is provided. In one aspect, the lid assembly includes a lid plate having an upper and lower surface, a manifold block disposed on the upper surface having one or more cooling channels formed therein, and one or more valves disposed on the manifold block. The lid assembly also includes a distribution plate disposed on the lower surface having a plurality of apertures and one or more openings formed there-through, and at least two isolated flow paths formed within the lid plate, manifold block, and distribution plate. A first flow path of the at least two isolated flow paths is in fluid communication with the one or more openings and a second flow path of the at least two isolated flow paths is in fluid communication with the plurality of apertures.

### BACKGROUND OF THE INVENTION

1. Field of the Invention

Embodiments of the invention relate to processing hardware and methods of distributing fluid therein to facilitate the sequential deposition of a film on a workpiece.

2. Description of the Related Art

Atomic layer deposition (ALD) is a sequential deposition method which has demonstrated superior step coverage of deposited layers on a substrate surface. ALD is a technique that utilizes a phenomenon known as chemisorption to deposit a single monolayer of reactive molecules on a substrate surface, and typically requires three process steps. A first reactive precursor is introduced into a processing chamber to deposit a first monolayer of molecules on a substrate surface. A second reactive precursor is then introduced into the processing chamber to form a second monolayer of molecules adjacent the first monolayer. The adjacent monolayers are then allowed to react to form a desired film on the substrate surface. These process steps are repeated until a desired film thickness is formed.

There are many challenges associated with ALD techniques that greatly affect the cost of operation and ownership. For example, the rate of deposition is typically slower than conventional bulk deposition techniques because ALD is a cyclic process. There is also a greater likelihood of contamination and premature/unwanted deposition due to the highly reactive precursor species used in the chemisorption process. Contamination and unwanted deposition causes substantial down time to clean and prepare the ALD hardware.

There is a need, therefore, for an ALD process having increased deposition rates. There is also a need for an ALD process that reduces the possibility of contamination and unwanted deposition. There is still another need for ALD hardware capable of isolating precursor gases or reactive species prior to deposition. There is yet another need for ALD hardware capable of facilitating a faster rate of deposition.

### SUMMARY OF THE INVENTION

Embodiments of the invention include a lid assembly for an ALD processing system that has the ability to provide a faster rate of deposition and reduces the likelihood of contamination or unwanted deposition. In one aspect, the lid assembly includes a lid plate having an upper and lower surface, a manifold block disposed on the upper surface having one or more cooling channels formed therein, and one or more valves disposed on the manifold block. The lid assembly also includes a distribution plate disposed on the lower surface having a plurality of apertures and one or more openings formed there-through, and at least two isolated flow paths formed within the lid plate, manifold block, and distribution plate. A first flow path of the at least two isolated flow paths is in fluid communication with the one or more openings and a second flow path of the at least two isolated flow paths is in fluid communication with the plurality of apertures.

Embodiments of the invention also include a processing chamber having a chamber body, a support pedestal disposed within the chamber body, and a lid assembly disposed on the chamber body. The lid assembly includes a lid plate having an upper and lower surface, a manifold block disposed on the upper surface having one or more cooling channels formed therein, and one or more valves disposed on the manifold block. The lid assembly also includes a distribution plate disposed on the lower surface having a plurality of apertures and one or more openings formed there-through, and at least two isolated flow paths formed within the lid plate, manifold block, and distribution plate. A first flow path of the at least two isolated flow paths is in fluid communication with a first valve of the one or more valves and the one or more openings and a second flow path of the at least two isolated flow paths is in fluid communication with a second valve of the one or more valves and the plurality of apertures.

Embodiments of the invention further include a method for depositing a nitride film on a semiconductor workpiece. The method includes flowing a first process gas and a first purge gas into a processing chamber, and flowing a second process gas and a second purge gas into a processing chamber. The processing chamber includes a lid plate having an upper and lower surface, a manifold block disposed on the upper surface having one or more cooling channels formed therein, one or more valves disposed on the manifold block, a distribution plate disposed on the lower surface having a plurality of apertures and one or more openings formed there-through, and at least two isolated flow paths formed within the lid plate, manifold block, and distribution plate. A first flow path of the at least two isolated flow paths is in fluid communication with the one or more openings and a second flow path of the at least two isolated flow paths is in fluid communication with the plurality of apertures. In one aspect, the first process gas is selected from a group consisting of titanium tetrachloride, tungsten hexafluoride, tantalum pentachloride, titanium iodide, and titanium bromide. In another aspect, the second process gas is selected from the group consisting of ammonia, hydrazine, monomethyl hydrazine, dimethyl hydrazine, t-butylhydrazine, phenylhydrazine, 2,2′-azoisobutane, ethylazide, nitrogen, and combinations thereof.

### BRIEF DESCRIPTION OF THE DRAWINGS

FIG. 1 is a perspective view of a processing system having a lid assembly in accordance with one embodiment described herein.

FIG. 2 is an enlarged, partial cross section view of the lid assembly of FIG. 1.

FIG. 2A is an enlarged view of an upper surface of a distributor plate.

FIG. 3 is an enlarged view of an interface between a valve and manifold block of the lid assembly shown in FIG. 1.

FIG. 4 is an enlarged view of an interface between a manifold block and lid plate of the lid assembly shown in FIG. 1.

FIG. 5 is a section view of the processing system of FIG. 1 along lines 5-5.

FIG. 6 is an isometric, interior view of the processing system shown in FIG. 1.

FIG. 7 is an enlarged view of a purge gas insert disposable within the processing system.

FIG. 8 is a section view of the processing system of FIG. 1 along lines 8-8.

### DETAILED DESCRIPTION OF THE INVENTION

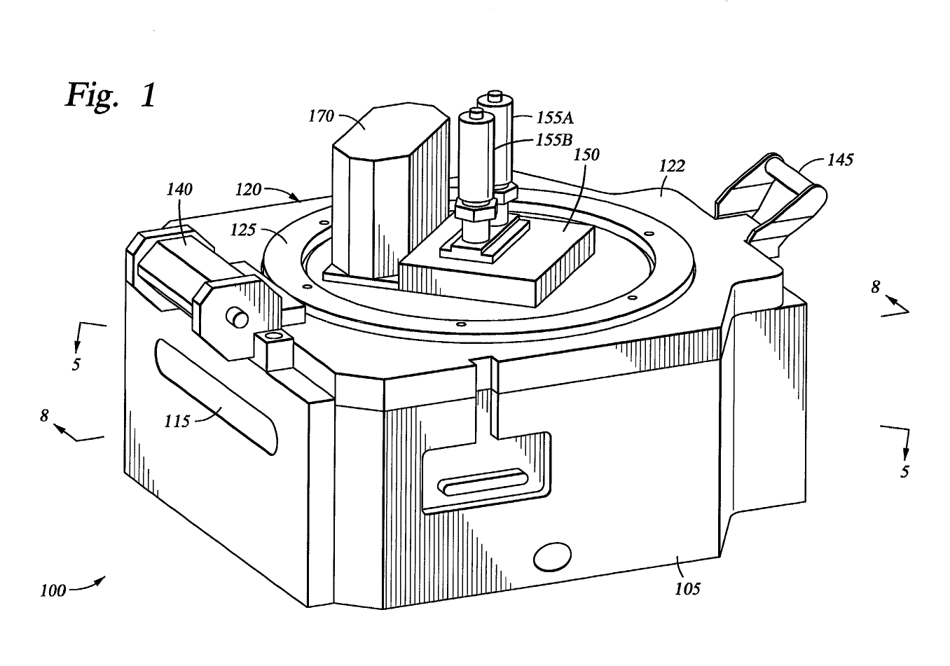

FIG. 1 is a perspective view of a processing system 100 having one or more isolated zones/flow paths to deliver one or more process gases to a workpiece/substrate surface disposed therein. The isolated zones/flow paths prevent exposure or contact of the precursor gases prior to deposition on the substrate surface. Otherwise, the highly reactive precursor gases may mix and form unwanted deposits within the processing system 100. Accordingly, the isolated zones/flow paths allow greater production throughput since less down time is required for cleaning the processing system 100. The isolated zones/flow paths also provide a more consistent and repeatable deposition process. The term “process gas” is intended to include one or more reactive gas, precursor gas, purge gas, carrier gas, as wells as a mixture or mixtures thereof.

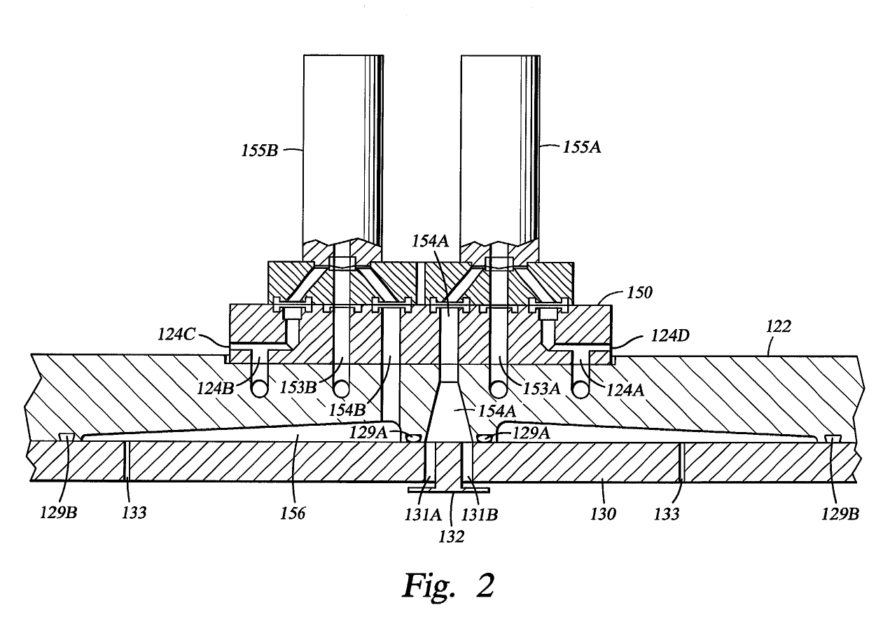

The processing system 100 includes a lid assembly 120 disposed on an upper surface of a chamber body 105 that form a fluid-tight seal there-between in a closed position. The lid assembly 120 includes a lid plate 122, a ring heater 125, a manifold block 150, one or more reservoirs 170, and a distribution plate 130 (shown in FIG. 2). The lid assembly 120 also includes one or more valves, preferably two high-speed valves 155A, 155B. The processing system 100 and the associated hardware are preferably formed from one or more process-compatible materials, such as aluminum, anodized aluminum, nickel plated aluminum, nickel plated aluminum 6061-T6, stainless steel, as well as combinations and alloys thereof, for example.

The ring heater 125, manifold block 150, and the one or more reservoirs 170 are each disposed on an upper surface of the lid plate 122. The one or more valves 155A, 155B are mounted on an upper surface of the manifold block 150. A handle 145 is disposed at one end of the lid plate 122, and a hinge assembly 140 is disposed at an opposite end of the lid plate 122. The hinge assembly 140 is connectable to the chamber body 105 and together with the handle 145 assists in the removal of the lid assembly 120, providing access to an interior of the chamber body 105. A workpiece (not shown) to be processed is disposed within the interior of the chamber body 105.

The ring heater 125 is disposed on an outer surface of the lid plate 122 to increase the surface temperature of the lid plate 122. The ring heater 125 may be attached to the lid plate 120 using one or more fasteners, such as screws or bolts, for example. In one aspect, the ring heater 125 may house one or more electrically resistive coils or heating elements (not shown). The ring heater 125 controls the temperature of the lid plate 122 to prevent the formation of unwanted adducts or byproducts of the process gases. Preferably, the temperature of the lid plate 122 is maintained above 90° C.

The manifold block 150 includes one or more cooling channels (not shown) disposed therein to remove heat transferred from the lid plate 122 as well as any heat generated from the high speed actuation of the valves 155A, 155B. The cooling effect provided by the manifold block 150 protects the valves 155A, 155B from early failure due to excessive operating temperatures and thus, promotes the longevity of the valves 155A, 155B. Yet, the cooling effect is controlled so as not to condense the process gas or otherwise interfere with the energy output of the ring heater 125. Preferably, the cooling channels (not shown) utilize cooling water as the heat transfer medium and are disposed about a perimeter of the manifold block 150.

The upper surface of the manifold block 150 is also coextensive with a lower surface of the valves 155A, 155B. For example, the coextensive surfaces may be milled to represent a w-shape, c-shape, or any other shape capable of providing a conformal, coextensive seal. A gasket (not shown) made of stainless steel or any other compressible and process compatible material, may be placed between the two coextensive surfaces and compressed to provide a fluid tight seal there-between.

The one or more reservoirs 170 each provide bulk fluid delivery to the respective valves 155A, 155B. Preferably, the lid assembly 120 includes one reservoir 170 for each process gas. In one aspect, the lid assembly 120 includes at least two reservoirs for a process gas. Each reservoir 170 contains between about 2 times the required volume and about 20 times the required volume of a fluid delivery cycle provided by the high speed valves 155A, 155B. The one or more reservoirs 170, therefore, insure a required fluid volume is always available to the valves 155A, 155B.

The valves 155A, 155B are high speed actuating valves having two or more ports. For example, the valves 155A, 155B may be electronically controlled (EC) valves, which are commercially available from Fujikin of Japan as part number FR-21-6.35 UGF-APD. The valves 155A, 155B precisely and repeatedly deliver short pulses of process gases into the chamber body 105. The valves 155A, 155B can be directly controlled by a system computer, such as a mainframe for example, or controlled by a chamber/application specific controller, such as a programmable logic computer (PLC) which is described in more detail in the co-pending U.S. patent application entitled “Valve Control System For ALD Chamber”, Ser. No. 09/800,881, filed on Mar. 7, 2001, which is incorporated by reference herein. The on/off cycles or pulses of the valves 155A, 155B are less than about 100 msec. In one aspect, the valves 155A, 155B are three-way valves tied to both a precursor gas source and a continuous purge gas source. As will be explained in more detail below, each valve 155A, 155B meters a precursor gas while a purge gas continuously flows through the valve 155A, 155B.

Considering the one or more isolated zones/flow paths in more detail, FIG. 2 shows a partial cross section of the lid assembly 120. Each isolated zone/flow path is formed throughout the lid assembly 120 and the chamber body 105. Each zone/flow path contains one or more process gases flowing therethrough. In one aspect, at least one zone/flow path delivers more than one process gas to the chamber body 105. For ease and simplicity of description, however, embodiments of the invention will be further described in terms of a two precursor gas deposition system. For a two precursor gas system, the processing system 100 will include at least two isolated zones/flow paths formed there-through. Each flow path, namely a first flow path and a second flow path, delivers its respective process gas to the workpiece surface within the chamber body 105.

The distribution plate 130 is disposed on a lower surface of the lid plate 122. The distribution plate 130 includes a plurality of apertures 133 surrounding one or more centrally located openings, preferably two openings 131A, 131B. FIG. 2A is an enlarged view of an upper surface of the distributor plate 130 illustrating the plurality of apertures 133 disposed about the openings 131A, 131B.

A process gas flowing through the first flow path enters the chamber body 105 and contacts the workpiece surface via the centrally located openings 131A, 131B. Although the openings 131A, 131B are shown as being circular or rounded, the openings 131A, 131B may be square, rectangular, or any other shape. A process gas flowing through the second flow path enters the chamber body 105 and contacts the workpiece surface via the plurality of apertures 133. The apertures 133 are sized and positioned about the distribution plate 130 to provide a controlled and even flow distribution across the surface of the workpiece.

A portion of the lower surface of the lid plate 122 is recessed so that a sealed cavity 156 is formed between the lid plate 122 and the distribution plate 130 when the distribution plate 130 is disposed on the lid plate 122. The apertures 133 of the distribution plate 130 are aligned within the cavity 156 so that the process gas flowing through the second flow path fills the cavity 156 and then evenly distributes within the chamber body 105 via the apertures 133.

The first and second flow paths are isolated at the distribution plate 130 by one or more o-ring type seals disposed on a lower surface of the lid plate 122. The lower surface of the lid plate 122 includes one or more concentric channels, preferably two channels 129A, 129B, formed therein to house an elastomeric seal. The elastomeric seal forms an o-ring type seal and can be made of any process compatible material, such as a plastic, elastomer, or the like, which is capable of providing a fluid, tight seal between the distribution plate 130 and the lid plate 122.

In one aspect, an inner-most channel 129A is formed about the centrally located openings 131A, 131B, and an outer-most channel 129B is formed near an outer diameter of the distribution plate 130, surrounding the cavity 156. The first flow path is contained by the inner-most o-ring 129A, and the second flow path is contained by the outer-most o-ring 129B. Accordingly, the first and second flow paths are isolated from each other by the inner-most o-ring 129A, and the outermost o-ring 129B contains the second flow path within the diameter of the distribution plate 130.

In another aspect, a plurality of additional channels are formed within the lid plate 122 and are located between the inner-most channel 129A and the outermost channel 129B. Each additional channel forms an additional, isolated zone/flow path through the distribution plate 130.

A dispersion plate 132 is also disposed within a portion of the first flow path. The dispersion plate 132 is disposed on a lower surface of the distribution plate 130, adjacent an outlet of the openings 131A, 131B. The distribution plate 130 and dispersion plate 132 may be milled from a single piece of material, or the two components may be milled separately and affixed together. The dispersion plate 132 prevents the process gas flowing through the first flow path from impinging directly on the workpiece surface by slowing and re-directing the velocity profile of the flowing gases.

Although various orientations of the workpiece are envisioned, the workpiece is preferably disposed horizontally or substantially horizontally within the chamber body 105. Accordingly, the process gas exiting the openings 131A, 131B flows substantially orthogonal to the workpiece surface. The dispersion plate 132, therefore, re-directs the substantially orthogonal velocity profile into an at least partially, non-orthogonal velocity profile. In other words, the dispersion plate 132 causes the process gas to flow radially outward, both vertically and horizontally, toward the workpiece surface there-below. Preferably, a cross-sectional area of the dispersion plate 132 is large enough to substantially reduce the kinetic energy of the process gas passing through the openings 129A, 129B. However, the cross-sectional area of the dispersion plate 132 is small enough so not to prevent deposition on the workpiece surface directly in line with the openings 131A, 131B.

The re-directed flow resembles an inverted v-shape and provides an even flow distribution across the workpiece surface. The increased cross sectional area provided by the inverted v-shape decreases the velocity of the process gas thereby reducing the force directed on the workpiece surface. Without this re-direction, the force asserted on the workpiece by the process gas can prevent deposition because the kinetic energy of the impinging process gas can sweep away reactive molecules already disposed on the workpiece surface. Accordingly, retarding and re-directing the process gas in a direction at least partially, non-orthogonal to the workpiece surface provides a more uniform and consistent deposition.

Still referring to FIG. 2, the first flow path further includes an inlet precursor gas channel 153A, an inlet purge gas channels 124A, the valve 155A, and an outlet process gas channel 154A that is in fluid communication with the openings 131A, 131B described above. Similarly, the second flow path further includes an inlet precursor gas channel 153B, an inlet purge gas channels 124B, the valve 155B, and an outlet process gas channel 154B that is in fluid communication with the apertures 133 described above. The inlet precursor gas channels 153A, 153B, the inlet purge gas channels 124A, 124B, and the outlet process gas channels 154A, 154B are formed within the lid plate 122 and the manifold block 150. The inlet precursor channels 153A, 153B are each connectable to a process gas source (not shown) at a first end thereof and connectable to the respective valve 155A, 155B at a second end thereof. The inlet purge gas channels 124A, 124B transfer one or more purge gases from their sources (not shown) to the respective valve 155A, 155B. The outlet gas channel 154B is connectable to the second valve 155B at a first end thereof and feeds into the chamber body 105 at a second end thereof via the cavity 156. The outlet gas channel 154A is connectable to the first valve 155A at a first end thereof and feeds into the chamber body 105 at a second end thereof via the openings 131A, 131B. An inner diameter of the gas channel 154A gradually increases within the lid plate 122. The inner diameter increases to mate or match the outer diameter of the openings 131A, 131B. The inner diameter also increases so that the velocity of the process gas is substantially decreased. The increased diameter of the gas channel 154A in addition to the dispersion plate 132 substantially decrease the kinetic energy of the process gas within the first flow path and thus, substantially improve deposition on the workpiece surface there-below.

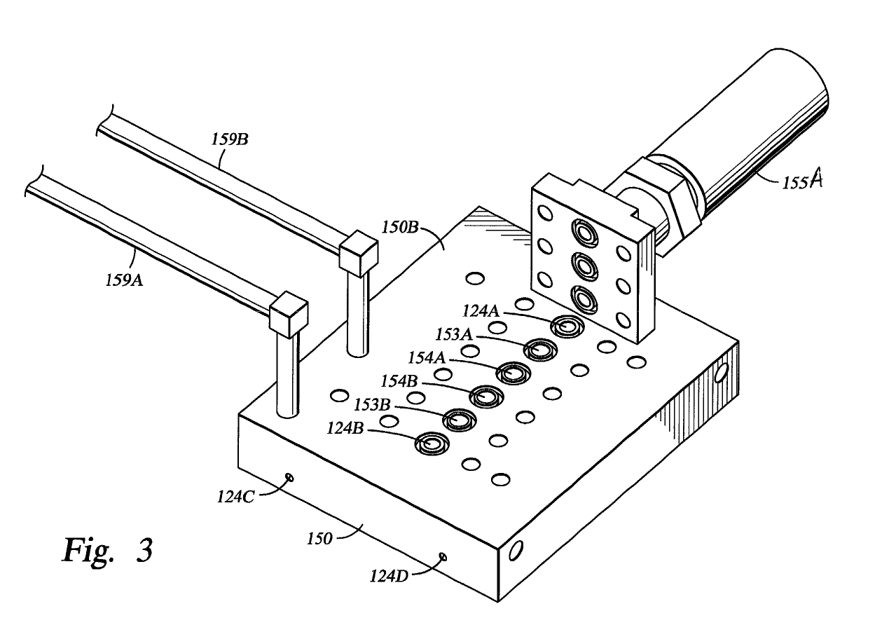

Considering the first and second flow paths in more detail, FIG. 3 shows an enlarged view of an upper surface 150B of the manifold block 150. As shown, the gas channels 124A, 124B, 153A, 153B, 154A, 154B, are aligned in a substantially straight line on the upper surface 150B of the manifold block 150 to accommodate the inlet and outlet port configuration of the valves 155A, 155B. The gas channels 124A, 124B, 153A, 153B, 154A, 154B, are surrounded by the one or more cooling channels (not shown) which are serviced by a coolant supply line 159A and a coolant return line 159B.

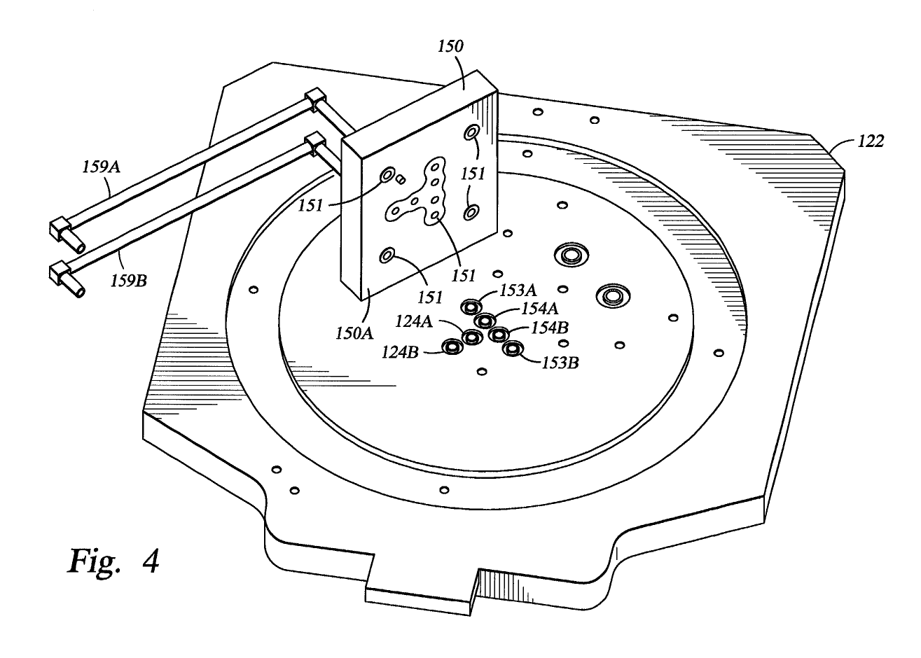

FIG. 4 shows an enlarged view of a lower surface 150A of the manifold block 150. As shown, the gas channels 124A, 124B, 153A, 153B, 154A, 154B, entering the manifold block 150 are arranged in a “T” shape configuration. The “T” shape configuration centrally locates the inlet of the gas channels on the lower surface 150A of the manifold block 150 to best optimize the surface area of the manifold block 150. The central location of the gas channels 124A, 124B, 153A, 153B, 154A, 154B, isolates the gas channels 124A, 124B, 153A, 153B, 154A, 154B, from the perimeter of the manifold block 150 where the one or more cooling channel (not shown) are disposed. This configuration minimizes the cooling effect on the process gases while maximizing the cooling effect on the valves 155A, 155B. Otherwise, the manifold block 150 would have to be much larger to distance the gas channels 124A, 124B, 153A, 153B, 154A, 154B, from the cooling channels which would substantially increase the conductive surface area of the manifold block 150 in contact with the lid plate 122 and thereby, increase the heat duty of the manifold block 150.

To form the manifold block 150 having the “T” shape configuration on its lower surface, the gas channels 153A, 153B, 154A, and 154B, are formed substantially vertically through the manifold block 150. Since a first end of the gas channels 124A, 124B disposed on the lower surface 150A of the manifold block 150 are not aligned with a second end of the gas channels 124A, 124B disposed on an upper surface 150B of the manifold block 150, both horizontal and vertical paths are formed through the manifold block 150. The horizontal paths are required to connect the first end of the gas channels 124A, 124B with the second end of the gas channels 124A, 124B. After the horizontal paths are milled into the manifold block 150, the ends thereof are capped, such as with a welded plug 124C, 124D shown in FIG. 2, for example. Accordingly, the purge gases flowing through the gas channels 124A, 124B travel up, over, and up through the manifold block 150 to the valves 155A, 155B.

Furthermore, the lower surface 150A of the manifold block 150 is configured to reduce the surface area in contact with the lid plate 122 because the less surface area in contact with the heated lid plate 122, the less amount of energy is transferred. Accordingly, the manifold block 150 includes one or more spacers 151 disposed about the fluid connections formed on the lower surface 150A thereof. In one aspect, the spacers extend about 0.001 mm to about 30 mm from the lower surface 150A of the manifold block 150, and are milled with the manifold block 150 from a single piece of material. The spacers 151 allow the manifold block 150 to be sealingly connected to an upper surface of the lid plate 122 while significantly reducing the contact surface area between the manifold block 150 and the lid plate 120.

During operation of the processing system 100 (referring back to FIG. 2), the outlet process gas channel 154A carries a process gas from the first valve 155A, through the manifold block 150, through the lid plate 122, and through the openings 131A, 131B into the chamber body 105. The outlet process gas channel 154B carries a purge gas and a precursor compound from the second valve 155B through the manifold block 150, through the lid plate 122 and into the cavity 156. As mentioned above, the cavity 156 is a sealed volume between the lid plate 122 and the distribution plate 130, and is isolated by the inner seal ring 129A and the outer seal ring 129B. Process gases within the gas channel 154B then flow from the cavity 156, through the apertures 133 into the chamber body 105. As a result, the process gases flowing through the outlet gas channel 154A are completely isolated from the process gases flowing through the outlet gas channel 153B.

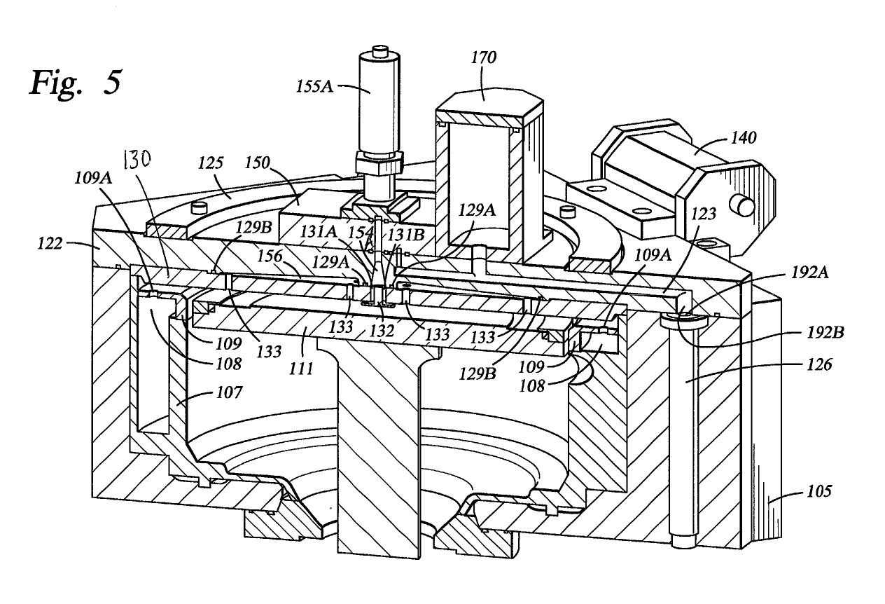

The process gases may be introduced directly from their respective source to the lid assembly 120 or alternatively, delivered to the lid assembly 120 via the chamber body 105. For example, the chamber body 105 may include one or more fluid delivery conduits 126 disposed therein as shown in FIG. 5 which shows a section view of a processing system 100 of FIG. 1 along lines 5-5.

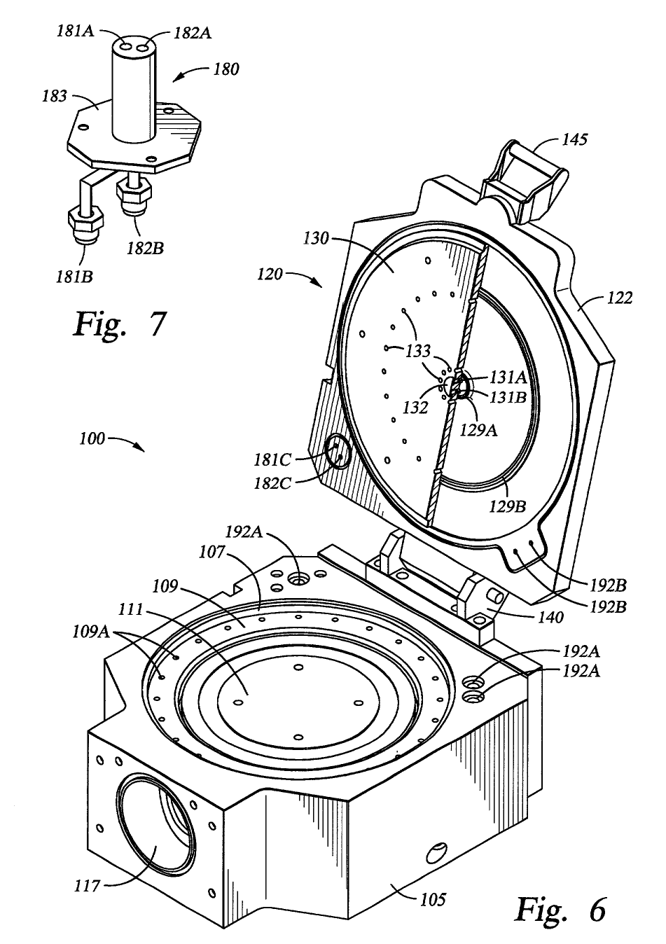

Referring to FIG. 5, the one or more fluid delivery conduits 126 (only one delivery conduit 126 is shown) are preferably disposed about a perimeter of the chamber body 105. The fluid delivery conduits 126 carry the one or more process gases from their respective source (not shown) to the lid assembly 120. In one aspect, two or more process gases may utilize the same fluid delivery conduit 126, but preferably, each fluid delivery conduit 126 services one process gas. For the two precursor deposition process, the chamber body 105 will include four fluid delivery conduits 126, one for each precursor and one for each purge gas because as will be explained in more detail below, each precursor gas has its own purge gas which may or may not be the same for each precursor gas. Each fluid delivery conduit 126 is connectable to a fluid source (not shown) at a first end thereof and has an opening/port 192A at a second end thereof. The opening 192A is connectable to a respective receiving port 192B disposed on a lower surface of the lid plate 122, as shown in FIG. 6 which shows an isometric view of an interior of the processing system 100.

Referring to FIGS. 5 and 6, the receiving port 192B is formed on a first end of a fluid channel 123 that is formed within the lid plate 122. When the lid plate 122 is closed, the opening 192A is placed in fluid communication with the receiving port 192B. Therefore, a fluid may flow from the fluid delivery conduit 126, through the ports 192A and 192B, to the fluid channel 123. This connection facilitates the delivery of a fluid from its source (not shown), through the lid plate assembly 120, and ultimately to within the chamber body 105.

Optionally, a gas insert 180 as shown in FIG. 7 may be used to facilitate a connection with a fluid channel 123. The gas insert 180 is a tubular member having one or more channels 181B, 182B, disposed therein. Each channel 181B, 182B is connectable to a source of fluid, such as one or more purge gases, at a first end thereof and includes openings181A, 182A at a second end thereof. The gas insert 180 is disposable within a fluid delivery conduit 126. Each opening 181A and 182A is placed in fluid communication with a receiving port 181C, 182C disposed on the lid plate 122 when the lid plate 122 is in a closed position. The gas insert 180 further includes a mounting plate 183 that is attachable to a lower surface of the chamber body 105 using well known methods, such as a screw or bolt, for example.

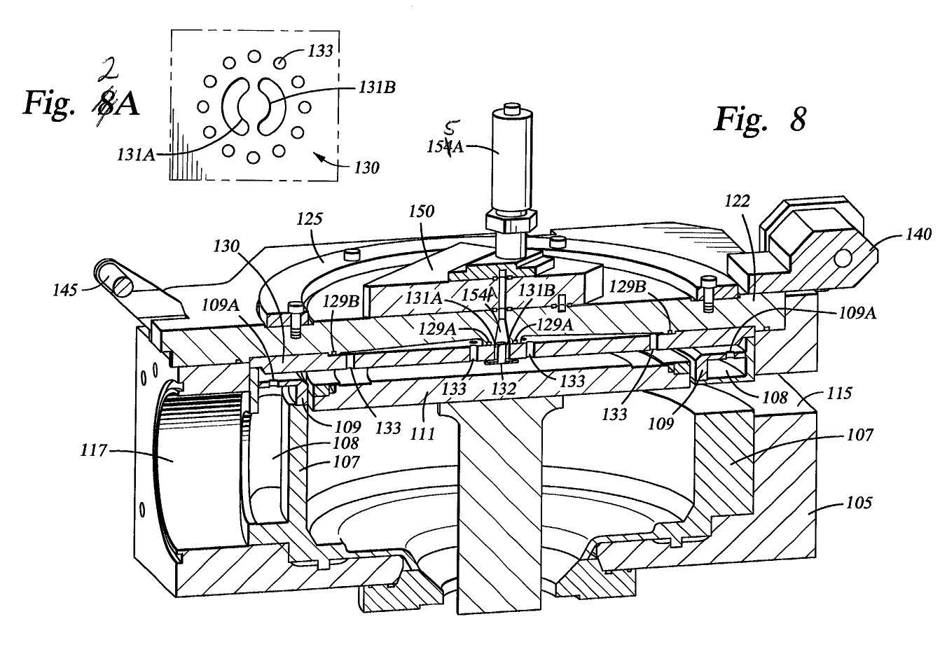

FIG. 8 shows a section view of a processing system of FIG. 1 along lines 8-8 and will be used to further describe the chamber body 105. The chamber body 105 includes a pumping plate 109, a liner 107, a support pedestal 111, and a slit valve 115 disposed therein. The slit valve 115 is formed within a side wall of the chamber body 105 and allows transfer of a workpiece (not shown) to and from the interior of the chamber body 105 without compromising the fluid-tight seal formed between the lid assembly 120 and the chamber body 105. Any conventional workpiece transfer assembly (not shown) may be used, such as a robotic wafer transfer assembly, for example. One example of a conventional robotic wafer transfer assembly is described in the commonly assigned U.S. patent titled “Multi-chamber Integrated Process System”, (U.S. Pat. No. 4,951,601), which is incorporated by reference herein.

The support pedestal 111 is disposed within the chamber body 105 and includes a lifting mechanism (not shown) to position a workpiece (not shown), such as a semiconductor wafer for example, therein. One example of a lifting mechanism for the support pedestal 111 is described in the commonly assigned U.S. patent, entitled “Self-Aligning Lift Mechanism”, (U.S. Pat. No. 5,951,776), which is incorporated by reference herein. The support pedestal 111 may be heated to transfer heat to the workpiece (not shown) depending on the requisite process conditions. The support pedestal 111 may be heated by applying an electric current from an AC power supply (not shown) to a heating element (not shown) embedded within the support pedestal 111. Alternatively, the support pedestal 111 may be heated by radiant heat emitted from a secondary source (not shown) as is known in the art. Further, the support pedestal 111 may be configured to hold the workpiece (not shown) using vacuum pressure. In this arrangement, the support pedestal 111 includes a plurality of vacuum holes (not shown) placed in fluid communication with a vacuum source (not shown).

The liner 107 is disposed about the support pedestal 111 and circumscribes the interior, vertical surfaces of the chamber body 105. The liner 107 is constructed of any process compatible material named above, such as aluminum, and is preferably made of the same material as the chamber body 105. A purge channel 108 is formed within the liner 107 and is in fluid communication with a pumping port 117 that extends through a side wall of the chamber body 105. A pump system (not shown) is connectable to the chamber body 105 adjacent the pumping port 117, and helps direct the flow of fluids within the chamber body 105.

The pumping plate 109 defines an upper surface of the purge channel 108 and controls the flow of fluid between the chamber body 105 and the pumping port 117. The pumping plate 109 is an annular member having a plurality of apertures 109A formed there-through. The diameter, number, and position of apertures 109A formed in the pumping plate 109 restrict the flow of gases exiting the chamber body 105 thereby containing the gases in contact with a workpiece (not shown) disposed within the chamber body 105. The apertures 109A provide consistent and uniform deposition on the workpiece.

Since the volume of the purge channel 108 is not consistent around the perimeter of the chamber body 105, the diameter, number, and position of apertures 109A are strategically arranged on the pumping plate 109. For example, the purge channel 108 has a smaller cross sectional area around the slit valve 115 to accommodate the transfer of the workpieces in and out of the chamber body 105. Accordingly, the size, orientation, and number of apertures 109A must be specifically designed and engineered so that uniform fluid flow about the perimeter and surface of the workpiece is achieved.

The processing system 100 may further include a remote plasma source (not shown) to clean contaminants or particles formed on interior surfaces thereof. A plasma of reactive species may be generated by applying an electric field to a process gas, such as hydrogen, nitrogen, oxygen-containing compounds, fluorine-containing compounds, and mixtures thereof, for example, within the remote plasma source. Typically, the electric field is generated by a RF or microwave power source (not shown). The reactive species are then introduced into the processing system 100 to reactively clean and remove unwanted particles.

Furthermore, a microprocessor controller (not shown) may be coupled to the processing system 100 to monitor or operate the processes performed therein. The microprocessor controller may be one of any general purpose, computer processing units (CPU) used for controlling various chambers and sub-processors. The CPU may use any suitable memory, such as random access memory, read only memory, floppy disk drive, hard disk, or any other form of digital storage, local or remote. Various support circuits may be coupled to the CPU for supporting the processor in a conventional manner.

Software routines, as required, may be stored in the memory or executed by a second CPU (not shown) that is remotely located. The software routines, when executed, transform the general purpose computer into a specific process computer that controls the chamber operation so that a chamber process is performed. Alternatively, the software routines may be performed by the hardware, as an application specific integrated circuit or other type of hardware implementation, or a combination of software or hardware.

The processing system 100 described above may be used to deposit various metal-containing films or layers on a workpiece surface. The processing system 100 may take advantage of metal-containing films, such as aluminum, copper, titanium, tantalum, tungsten, and combinations thereof, for example. To deposit these films, various reactive metal-containing compounds may be used, such as titanium tetrachloride (TiCl₄), tungsten hexafluoride (WF₆), tantalum pentachloride (TaCl₅), titanium iodide (Til₄), and titanium bromide (TiBr₄), for example. The metal-containing compounds may also include metal organic compounds, such as tetrakis(dimethylamido)titanium (TDMAT), pentakis(dimethyl amido) tantalum (PDMAT), tetrakis(diethylamido)titanium (TDEAT), tungsten hexacarbonyl (W(CO)₆), tungsten hexachloride (WCl₆), tetrakis(diethylamido) titanium (TDEAT), pentakis (ethyl methyl amido) tantalum (PEMAT), and pentakis(diethylamido)tantalum (PDEAT), for example. Suitable nitrogen-containing compounds include ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), nitrogen (N₂), and combinations thereof, for example.

For simplicity and ease of description, however, a process for depositing a titanium nitride film using ammonia (NH₃) and titanium chloride (TiCl₄) within the processing system 100 will be described in more detail below.

Referring to FIG. 8, a workpiece, such as a semiconductor wafer for example, is inserted into the chamber body 105 through the slit valve 115 and disposed on the support pedestal 111. The support pedestal 111 is lifted to a processing position within the chamber body 105. A purge gas, such as argon, helium, hydrogen, nitrogen, or mixtures thereof, for example, is allowed to flow and continuously flows during the deposition process. Preferably, the purge gas is argon. The purge gas flows through its fluid delivery conduit 126 to its designated fluid channel 123, through the manifold block 150, through its designated valve 155A or 155B, back through the manifold block 150, through the lid plate 122, through the distribution plate 130, and into the chamber body 105. As explained above, a separate purge gas channel is provided for each of the valves 155A, 155B because the flow rate of the purge gas is dependent on the differing flow rates of the precursor gases, ammonia and titanium tetrachloride.

Referring back to FIG. 5, the precursor gases, ammonia and titanium chloride, are introduced into the chamber body 105 in a similar fashion. However, each precursor gas flows from its source (not shown) through its fluid delivery conduit 126 into its designated fluid channel 123, into its designated reservoir 170, through the manifold block 150, through its designated valve 155A or 155B, back through the manifold block 150, through the lid plate 122, and through the distribution plate 130. More particularly, a first purge gas and a first reactant gas, either the ammonia or titanium tetrachloride, flows through the slotted openings 131A, 131B formed in the dispersion plate 130; whereas, a second purge gas and a second reactant, the other of ammonia or titanium tetrachloride, flows through the apertures 133 formed in the dispersion plate 130. As explained above, the flow path through the slotted openings 131A, 131B and the flow path through the apertures 133 are isolated from one another by the o-ring seals disposed in the o-ring channels 129A, 129B. The first purge gas and first precursor gas flowing through the slotted openings 131A, 131B are deflected by the dispersion plate 132. The dispersion plate 132 converts the substantially downward, vertical flow profile of the gases into an at least partially horizontal flow profile. More particularly, the process gases flowing into the dispersion plate 132 are deflected radially, both horizontally and vertically toward the workpiece surface disposed there below.

During deposition, a monolayer of nitrogen atoms is first chemisorbed on the wafer by introducing a pulse of ammonia into the chamber body 105 through the second valve 155B simultaneous with the continuous flow of a first purge gas. Since the second valve 155B is preferably a three-way valve, the first purge gas flows simultaneously into the chamber body 150 through the valves 155B with the ammonia. The pulse time for ammonia is typically less than about 5 seconds. Next, a pulse of titanium tetrachloride is introduced into the chamber body 105 through the first valve 155A simultaneous with the continuous flow of a second purge gas. Since the first valves 155A is preferably a three-way valve, the second purge gas flows simultaneously into the chamber body 150 through the valve 155A with the titanium tetrachloride. The pulse time for titanium tetrachloride is typically less than about 2 seconds. As stated above, the first and second purge gases are both preferably argon, but the first and second purge gases may be different. For example, the first purge gas may be nitrogen while the second purge gas is argon.

Titanium tetrachloride reacts with surface nitrogen atoms to form a titanium nitride layer. The reaction step usually requires between about 0.001 and 1 seconds. Any unreacted compounds, residual compounds, and by-products from the wafer surface are removed from the chamber body 105 by the vacuum system (not shown but described above) as well as by the continuous flow of purge gas. The process steps are then repeated until a desired thickness of the titanium nitride layer is achieved. Preferably, a titanium nitride layer having a thickness between about 100 angstroms and 5,000 angstroms is formed on the wafer surface.

Although the process has been described above by first depositing an ammonia monolayer followed by a titanium tetrachloride monolayer, a reversed sequence may satisfactorily obtain similar results. In other words, a titanium tetrachloride monolayer may be first deposited followed by the deposition of an ammonia monolayer. Likewise, any subsequent deposition step may utilize the same or reverse order of deposition.

Additional details for forming metal nitride layers are described in commonly assigned U.S. patent application entitled, “Bifurcated Deposition Process for Depositing Refractory Metal Layer Employing Atomic Layer Deposition and Chemical Vapor Deposition, (Ser. No. 09/605,596); U.S. patent application entitled, “Methods and Apparatus for Depositing Refractory Metal Layers Employing Sequential Deposition Techniques to Form Nucleation Layers”, (Ser. No. 09/678,266); and U.S. patent entitled “Low Resistivity W Using B₂H₆ Nucleation Step”, (U.S. Pat. No. 6,099,904), which are all incorporated by reference herein.

What is claimed is:

1. A lid assembly for a processing system, comprising:
a lid plate having an upper and lower surface;
a manifold block disposed on the upper surface having one or more cooling channels formed therein;
one or more valves disposed on the manifold block; and
a distribution plate disposed on the lower surface having a plurality of apertures and one or more openings formed there-through; and
at least two isolated flow paths formed within the lid plate, manifold block, and distribution plate;
wherein a first flow path of the at least two isolated flow paths is in fluid communication with the one or more openings and a second flow path of the at least two isolated flow paths is in fluid communication with the plurality of apertures.

2. The lid assembly of claim 1, further comprising a heater disposed on the upper surface of the lid plate.

3. The lid assembly of claim 1, wherein the one or more valves are each three-way valves and simultaneously deliver a purge gas and a precursor gas to either the first flow path or the second flow path.

4. The lid assembly of claim 1, wherein the plurality of apertures are disposed about the one or more openings.

5. The lid assembly of claim 1, wherein the first flow path is a centrally located flow channel at least partially disposed within the lid plate having a gradually increasing cross-sectional area that resembles an inverted v-shape.

6. The lid assembly of claim 1, wherein the lower surface of the lid plate is at least partially recessed to define a cavity when the distribution plate is disposed on the lid plate.

7. The lid assembly of claim 6, wherein the cavity is a fixed volume contained by at least one inner o-ring and at least one outer o-ring disposed on the inner surface of the lid plate.

8. The lid assembly of claim 7, wherein the plurality of apertures are in fluid communication with the cavity.

9. The lid assembly of claim 1, further comprising a dispersion plate disposed adjacent the one or more openings.

10. The lid assembly of claim 9, wherein the dispersion plate re-directs a velocity profile of a process gas flowing through the first flow path.

11. The lid assembly of claim 10, wherein the velocity profile is re-directed to be at least partially non-orthogonal to a workpiece surface.

12. A processing chamber, comprising;
a chamber body;
a support pedestal disposed within the chamber body; and
a lid assembly disposed on the chamber body, the lid assembly, comprising:
a lid plate having an upper and lower surface;
a manifold block disposed on the upper surface having one or more cooling channels formed therein;
one or more valves disposed on the manifold block; and
a distribution plate disposed on the lower surface having a plurality of apertures and one or more openings formed there-through; and
at least two isolated flow paths formed within the lid plate, manifold block, and distribution plate;
wherein a first flow path of the at least two isolated flow paths is in fluid communication with a first valve of the one or more valves and the one or more openings and a second flow path of the at least two isolated flow paths is in fluid communication with a second valve of the one or more valves and the plurality of apertures.

13. The lid assembly of claim 12, further comprising a heater disposed on the upper surface of the lid plate.

14. The lid assembly of claim 12, wherein the one or more valves are each three-way valves and simultaneously deliver a purge gas and a precursor gas to either the first flow path or the second flow path.

15. The lid assembly of claim 12, wherein the plurality of apertures are disposed about the one or more openings.

16. The lid assembly of claim 12, wherein the first flow path is a centrally located flow channel at least partially disposed within the lid plate having a gradually increasing cross-sectional area that resembles an inverted v-shape.

17. The lid assembly of claim 12, wherein the lower surface of the lid plate is at least partially recessed to define a cavity when the distribution plate is disposed on the lid plate.

18. The lid assembly of claim 17, wherein the cavity is a fixed volume contained by at least one inner o-ring and at least one outer o-ring disposed on the inner surface of the lid plate.

19. The lid assembly of claim 18, wherein the plurality of apertures are in fluid communication with the cavity.

20. The lid assembly of claim 12, further comprising a dispersion plate disposed adjacent the one or more openings.

21. The lid assembly of claim 20, wherein the dispersion plate re-directs a velocity profile of a process gas flowing through the first flow path.

22. The lid assembly of claim 21, wherein the velocity profile is re-directed to be at least partially non-orthogonal to a workpiece surface.

23. A method for depositing a nitride film on a semiconductor workpiece, comprising:
flowing a first process gas and a first purge gas into a processing chamber; and
flowing a second process gas and a second purge gas into a processing chamber,
wherein the processing chamber comprises:
a lid plate having an upper and lower surface;
a manifold block disposed on the upper surface having one or more cooling channels formed therein;
one or more valves disposed on the manifold block; and
a distribution plate disposed on the lower surface having a plurality of apertures and one or more openings formed there-through; and
at least two isolated flow paths formed within the lid plate, manifold block, and distribution plate;
wherein a first flow path of the at least two isolated flow paths is in fluid communication with the one or more openings and a second flow path of the at least two isolated flow paths is in fluid communication with the plurality of apertures.

22. The method of claim 21, wherein the first process gas is selected from the group consisting of titanium tetrachloride, tungsten hexafluoride, tantalum pentachloride, titanium iodide, and titanium bromide.

23. The method of claim 21, wherein the first process gas is selected from the group consisting of tetrakis(dimethylamido)titanium, pentakis(dimethylamido) tantalum, tetrakis(diethylamido)titanium, tungsten hexacarbonyl, tungsten hexachloride, tetrakis(diethylamido) titanium, and pentakis(diethylamido)tantalum.

24. The method of claim 21, wherein the first process gas is titanium tetrachloride.

25. The method of claim 21, wherein the second process gas is selected from the group consisting of ammonia, hydrazine, monomethyl hydrazine, dimethyl hydrazine, t-butylhydrazine, phenylhydrazine, 2,2′-azoisobutane, ethylazide, nitrogen, and combinations thereof.

26. The method of claim 21, wherein the second process gas is ammonia.

27. The method of claim 21, wherein the first process gas is titanium tetrachloride and the second process gas is ammonia.

28. The method of claim 21, wherein the purge gas comprises argon, helium, hydrogen, nitrogen, or combinations thereof.

29. The method of claim 21, wherein the workpiece is a semiconductor wafer.

30. The method of claim 31, wherein the second process gas flows through the plurality of apertures and the first process gas flows through the one or more openings.
